(19) United States
(12) Patent Application Publication
(10) Pub. No.: US 2025/0121419 A1
(43) Pub. Date: Apr. 17, 2025

(54) Method for separating reusable materials in a composite component

(71) Applicant: FLAXTEC GMBH, Dresden (DE)

(72) Inventor: Harald GROSS, Langebrück (DE)

(73) Assignee: FLAXTEC GMBH, Dresden (DE)

(21) Appl. No.: 18/833,970

(22) PCT Filed: Apr. 28, 2022
(86) PCT No.: PCT/DE2022/200078

§ 371 Date: Jul. 29, 2024

(30) Foreign Application Priority Data
Feb. 7, 2022 (DE) 10 2022 102 778.3
Apr. 14, 2022 (DE) 10 2022 109 347.6

(51) Int. Cl. B09B 3/50; B09B 3/30; B09B 101/15; B09B 101/75

(52) U.S. Cl. CPC B09B 3/50; B09B 3/30; B09B 2101/15; B09B 2101/75

(57) ABSTRACT

A method for separating reusable materials of a composite component comprising multiple material layers is presented. The composite component comprises a material layer which absorbs energy of a radiation source and at least one plastics film. With the aid of the radiation source, the composite component is heated in less than a second in an exposure field, with chemical compounds of the plastics material being cleaved, as a result of the heating of the absorbing material layer, in a boundary layer of the at least one plastics film which faces the absorbing material layer, resulting in a creation of gas. Prior to heating, at least one predetermined breaking point is introduced into the plastics film in such a way that the plastics film breaks in a controlled fashion at the predetermined breaking point under the pressure of the created gas.

### CROSS-REFERENCE TO RELATED APPLICATION

This application is a national stage application, filed under 35 U.S.C. § 371, of International Patent Application PCT/DE2022/200078, filed on Apr. 28, 2022, which claims the benefit of German Patent Applications DE 10 2022 102 778.3, filed on Feb. 7, 2022, and DE 10 2022 109 347.6, filed on Apr. 14, 2022.

### BACKGROUND

The disclosure relates generally to a method for separating reusable materials in a composite component comprising at least one material layer which absorbs the energy of an electromagnetic radiation source and at least one plastics film. Alternatively, the plastics film may adjoin the absorbing material layer directly or indirectly with the interposition of a thermally conductive layer, and thus form a layer sequence which absorbs the energy of the electromagnetic radiation source, referred to hereinafter as radiation source for short. In a separating method of the generic type, the absorbing material layer or layer sequence is heated in less than a second with the aid of the radiation source in an exposure field. The disclosure relates in particular to methods for separating reusable materials in solar energy modules, such as photovoltaic modules or such as component parts of “concentrated solar power” modules, or from the field of displays.

Photovoltaic modules and displays come under the category of “electronic waste” following their use as intended, and contain valuable, reusable raw materials. In the European Union, electronic waste must be recycled according to EU directives. Depending on their design, the modules contain for example silicon wafers and silver or rare materials such as indium, gallium or tellurium and further materials in a composite.

A composite component consists of multiple component parts which cooperate during its use in order to realize its function and, for this purpose, are intended to remain connected to one another for the duration of the use of the composite component. Temporary connections of individual component parts among one another or to aids in the course of the production of composite components prior to the completion thereof shall not come under the term “composite component” used here.

The exposure field of the radiation source regularly comprises at least one portion of the surface of the composite component, thus resulting in the absorbing material layer and if appropriate with the latter the absorbing layer sequence being heated in sections or optionally completely.

A particular case for separating composite components is described in the patent application WO 2018/137735 A1. The radiation source preferred for the separation in that case is one or more gas discharge lamps for heating a reusable material in photovoltaic modules. The preferred reusable material is currently silicon. However, the method can also be applied to other materials and other composite components. Reference is made to the full scope of the contents of the method in WO 2018/137735 A1.

About 85% of all photovoltaic modules produced substantially consist of a composite of successive materials in the form of a layer stack: glass sheet/upper plastics film/multiple silicon wafers situated next to one another in a plane parallel to the glass sheet/film composite. The latter consists of multiple plastics films. The method for separating reusable materials of a composite component will be explained later on the basis of this example.

In WO 2018/137735 A1, intensive visible light 01 shines for less than a second through the glass sheet 02 of the front side of a photovoltaic module 00, for example illustrated in FIG. 1, and through the upper plastics film 03 adjoining that, said film being transparent to visible light, and is absorbed by the underlying material layer which absorbs the light of the radiation source, that is to say for example silicon wafers 04 which to a first approximation are square and are situated next to one another in one plane. On account of the light absorption, the material layer heats up and so the plastics films 03, 05 connected thereto become detached. In the process, pyrolysis gases are created in layers of the plastics materials with a thickness of a few micrometers which directly adjoin the absorbing material layer.

The plastics film of the film composite 05 which is directly connected to the silicon wafers typically consists of the same material as the upper plastics film 03. The film composite, comprising further films over and above those, is referred to as back-side film in the technical literature. Hereinafter for simplification of the film stacks 05 on the underside of the wafer shall be referred to as lower plastics film 05 and the film on the top side of the wafer shall be referred to as upper plastics film 03.

Between the silicon wafers there are regions 06 of plastics materials, called “webs” hereinafter, which are created during the production of the photovoltaic modules when the upper and lower plastics films 03, 05 are laminated onto the top side and respectively the underside of the wafers. In the above-described method in WO 2018/137735 A1, the webs 06 prevent complete separation of the films 03 from 05 by means of exposure. Consequently, after the exposure, the silicon typically remains in film pockets connected to one another at the webs. After the exposure, the lower plastics film still adheres to the upper plastics film by way of the webs.

Since multiple parameters of the composite components, such as the types of plastics materials, the dimensions of the wafers, their light absorptances and distances among one another, i.e. their web widths, and many others vary greatly not only between different manufacturers of the modules but also between module generations of one manufacturer, in cases of practical application it is almost impossible to set a light dose for separating the material layers which is optimal and at the same time standardized for all the module types. In order to ensure complete and reliable separation of the materials to be separated, for example of the semiconductor as absorbing material layer, e.g. of the silicon, from the plastics materials of the composite component in all cases, if possible, it is therefore necessary to choose a minimum temperature and a minimum light dose correlated therewith.

In the case of most photovoltaic modules, the minimum light dose results in the plastics materials being subjected to more extensive pyrolysis than is desired, and thus in excessive gas production and in blackish deposits on the silicon and the plastics material surfaces adjoining the latter. In practice, the separation of the material layer takes place in a manner that is not uniform, not repeatable and not at the same location, even for modules of the same type and with identical process parameters. In extreme cases, individual silicon fragments penetrate through the film stack 05 or become lodged in the latter on account of temperatures far above the minimum temperature and as a consequence of excessive gas production.

If the generally tempered upper cover glass has already broken before the exposure, then the glass sheet with fragments still connected to one another by the upper plastics film 03 may curve in the direction of the light source. In the process, pyrolysis gas may escape, fragments may become detached and, ultimately, the light source may also be adversely affected or even damaged. Some of the plastics materials of the film stack 05 have only a low mechanical loading capacity on account of their degree of aging in the UV light from the sun, with the result that the film stack 05 breaks up into many small pieces which mix with the silicon and thus necessitate costly subsequent sorting such as by an air classifier, for example.

### SUMMARY

The application presents a method for separating materials of a composite component which are able to be reused as reusable material, for example the semiconductor of the wafers, in particular the silicon or component parts other than the electronic component parts from the still existing composite with a glass sheet and/or one of the plastics films, in order to be able to extract them afterward.

In the method, a minimum light dose is intended to be optimized, in particular reduced in comparison with the known methods. This will make it possible, inter alia, to avoid the above-described negative effects and damage pertaining to the composite component or to the device.

Furthermore, the separation of the materials of the composite component and subsequently the extraction of the reusable materials thereof are intended to be realizable on an industrial scale and to be applicable here to composite components from different generations and manufacturers with a light dose that is constant or regulated in an automatable manner.

The separation of the reusable material takes place using the thermochemical decomposition of the boundary layer of the plastics film in the absence of oxygen in the boundary layer. The energy required for this is available, as described above with regard to the prior art, on account of the absorption of the radiation incident in less than a second by the absorbing material layer of the composite component.

The exposure duration depends in particular on the materials involved and their layer sequence in the composite component. It is evidently to be defined in such a way that the introduced radiation energy is sufficient to bring about the thermal decomposition and to ensure the creation of an amount of gas such that the plastics film is detached from the adjacent layer on account of the evolution of gas in the exposure field.

The exposure duration of an exposure for separating the layers can be significantly less than a second. It depends on many parameters associated with the absorption and heat transfer within the composite component. For various types of photovoltaic modules, the separation of the absorbing material layer can take place with exposure times for example in the range of 5 μs to 500 ms, as an alternative 100 μs to 100 ms, as a further alternative 500 μs to 50 ms. Even with exposure times of less than a millisecond, the method can be implemented and the reusable materials can be separated. All intermediate values can be usable depending on various parameters.

The exposure time depends for example on the material and the layer thickness of the absorbing material layer (in micrometers), and likewise on the material and the layer thickness of the adjoining material layers, since these determine the heat losses as a result of heat transfer, and moreover on the type and operation of the radiation source. A further parameter is the temperature to be attained for the thermal decomposition of the plastics material. An essential measure of the exposure duration is constituted by the material and layer thickness of the absorbing material layer, which is why thin-film solar modules, for example, the light-absorbing layer of which is thinner by approximately two orders of magnitude, may require distinctly different times.

The table below lists some of the aforementioned parameters for various absorbing materials by way of example, but in a nonlimiting manner.

All values are merely approximate values. The heat capacity is of secondary importance and is therefore not taken into consideration here. At relatively high temperatures, thermal radiation is of distinct importance since it is proportional to the fourth power of the temperature.

The light absorption is likewise an important factor; for example, silver and aluminum absorb principally in the UV range, which is why in this case shorter pulse durations are required for higher current densities in the flash lamps or a more intense UV emission.

The example of the windowpane is entered only for comparison, but does not contain a polymer.

After tempering, glass frit often and predominantly consists of glass and lead oxide. On account of the poor thermal conductivity of the glass frit, the exposure duration has to be very long at low intensity.

| | | Required | Exposure | Material |
|---|---|---|---|---|
| Absorbing | Embedding | temperature | duration | thickness |
| material layer | material | [C.] | [ms] | [um] |
| Silicon wafer | Polymer/polymer | approx. | 3-30 | 180-400 |
| (PV) | | 500-800 | | |
| Silver | Glass/air | approx. 400 | 0.05 | 0.01 |
| Thin-film | Glass/polymer | approx. 400 | 0.5 | 2 |
| photovoltaics | | | | |
| Aluminum | Polymer/hardboard | approx. 500 | 0.1 | 0.03 |
| Glass frit | Ceramic/glass | approx. 350 | 200 | 40 |

The above table shows only a few parameters for defining the exposure duration. For the respectively current case, the exposure duration should be determined on the basis of the conditions by way of experiments and/or simulation.

Within the meaning of the disclosure, exposure field is understood to be that areal section of a composite component in which the light from the external radiation source is incident. That also includes an exposure field of the size of the composite component or larger.

The term “external radiation source” here denotes such a source which is not part of the composite component, but is part of a device for performing the method.

Light dose is generally understood to be the radiation energy introduced into the composite component within the exposure field during an exposure process of a defined duration, relative to the treated mass. The latter is determined by the size of the composite component within an exposure field.

On the basis of the materials of the involved layers of the composite components to be treated in a method cycle and using suitable simulations and/or experiments, the minimum light dose preferred for a cycle is determinable.

On account of the described pyrolytic decomposition of a thin boundary layer of the plastics film with respect to the adjacent, hot material layer, gas-filled pockets are created over the radiation-absorbing material. The connection between both plastics layers, which connection has been described above with regard to the prior art and remains even after the exposure, results from the deficient absorption and hence deficient heating of the webs or other, non-absorbent or slightly absorbent constituents of the composite component and delimits the pockets.

The opening of the gas-filled pockets is initiated by means of one or more predetermined breaking locations in the lower plastics film and is realized optimally for all the predetermined breaking locations. As a result, the adjoining hot material layer is uncovered at least in sections. The at least one predetermined breaking location, preferably the multiple predetermined breaking locations, is/are produced in the plastics film before the exposure of the composite components.

The predetermined breaking locations allow a targeted opening of the plastics film in a manner that is reproducible for a wide variety of module types. On account of the condition of the minimum light dose for the treatment of different implementations of a type of composite components, excessively generated gas can escape, without causing negative consequences on the composite component or on the device. This is because excessively generated gases cannot build up such a high pressure between absorbing material layer and plastics film, and this precludes curving of the cover glass or an adverse effect on the light source if glass has broken. Fragments of the hot material layer are hurled out of the openings instead of penetrating through the plastics films or becoming lodged therein, as would happen without predetermined breaking locations.

Predetermined breaking location shall be understood here to be a local location of the lower plastics film which is determined by a particular structure and/or shape and which is introduced into the plastics film from the underside and breaks in a defined manner in the event of loading on account of the formation with gas-filled pockets. The predetermined breaking location can partly or completely penetrate through the plastics film.

The geometric shape of the predetermined breaking location can be as desired. For example, scored tracks or cuts can be introduced into the plastics films, in which case, in a first step, predetermined breaking locations are cut into the composite component and, in a second step, the reusable material embedded in the composite component is heated externally by a radiation source. As a result of the heating, separation of the composite materials takes place and gases are created in the process. The gases support the separation process and can emerge from the composite component in a targeted manner through the predetermined breaking locations. They can still contribute to the extraction of the reusable material during the exposure, with the result that a lower light dose is required for the separation of the silicon from the plastics materials.

Alternatively, the predetermined breaking locations can be formed in areal fashion, such as drilled holes or the like. Areal incisions can be uniformly distributed or concentrated at one or more locations, for example for each wafer surface. There is also the possibility of the plastics film being cut open not only at the edge of the wafer, i.e. with a square shape or in a U-shaped manner, but for example also into multiple smaller meander-shaped strips which remain connected to the webs on one side. This enables a further reduction of the gas pressure during pyrolysis. The local distribution of the predetermined breaking locations of a composite component should be implemented such that each expected pocket has at least one predetermined breaking location. The suitable geometric shape of the incisions, their depth and their distribution can be determined by experiments, for example, depending on the properties of the composite components to be recycled.

Predetermined breaking locations can be introduced for example by mechanical means, for example by a knife, preferably by a circular knife, or by a laser beam. Other methods with precise and variable cut guidance in regard to the shape and depth of the cut are also possible. For example, at the edge of each wafer the plastics film can be completely or partly cut open from the side facing away from the glass.

In one embodiment of the method, the exposure of the absorbing material layer takes place from that side at which the predetermined breaking locations face away from the light source, for example with a light source arranged above the composite component. The gravitational force can thus be utilized for separating the material of the absorbing layer from the carrier material thereof. Furthermore, in this way, the radiation source is protected from damage on account of high gas pressures during the thermal decomposition, or from contamination by soot from the gases.

In a further embodiment, composite components are treated which have at least one material layer which is transparent to visible light and/or UV light. Diverse composite components are known whose materials are intended to be recycled for reuse and which have a carrier layer or cover layer. If these are transparent to the light from the radiation source for the method, an exposure through this layer and a separation from this layer are possible.

The material layers are differentiated into transparent and further, light-absorbing layers according to their prevailing optical behaviors used for the separation process. In this regard, the transparent material layer forms the entrance window at least for the visible light from the external radiation source into the composite component and, for this purpose, has a transparency for the spectral range used for the separating process employed. Material layers having a transparency for visible light of more than 40% have proved to be suitable for the processes that can be used, where the percentages indicated for the transparency relate to the emission spectrum of the gas discharge lamp exhibiting regularly broadband emission. The at least one gas discharge lamp can optionally be operated as a flash lamp, such that the energy input into the composite component leads to a negligible increase in the temperature of the entire composite component.

Depending on the gas discharge lamp used, on the operating parameters thereof, on the separating process used and on the layer materials, the spectral transparency can also include other ranges in the emission spectrum besides the visible range, such as light in the UV range and/or IR range, for example.

The method can also be applied to composite components whose transparent material layers have higher transparency values or transparency profiles coordinated with the relevant spectral ranges. The transparency can be determined by one transparent material layer or a plurality thereof lying one above another.

In further embodiments of the method, the predetermined breaking locations can be formed in the plastics film in such a way that, in addition to uncovering the material layer to be obtained, they are also usable for the extraction and separation of said material layer from further constituents of the composite component.

If the plastics material is for example not cut open along closed paths, for example along the complete edge of a wafer, rather for example a section having a length of one centimeter is not cut open, then this has the effect that a film which is continuous in sections remains on the composite component. As a result, the separation of the different materials is facilitated and the further problems present from the prior art on account of overexposure of composite components can be reduced or entirely avoided.

Such a plastics film which is broken at the predetermined breaking locations but still continuous can support for example separation of the semiconductor reusable material from the metallic materials for making electrical contact with the semiconductor components, in particular from the busbars.

Busbars are generally tin-plated copper lines which electrically connect the wafers to one another and are guided through the webs. In this case, the connection almost always runs from the front side of one wafer to the back side of the adjacent wafer, such that the semiconductor diodes—one per wafer—are connected in series. If the abovementioned section that is not cut is now chosen exactly in that region of the wafer edge in which the busbars pass through the web, then after the exposure the busbars still adhere in the web or do not mix with the extracted semiconductor material, for example silicon. The semiconductor material can thus be extracted in type-specific fashion by the method.

For example, if an incision is made in only three sides of a wave edge, i.e. in a U-shaped manner, such that the busbars leading to the underside of the wafer are not severed, then this part of the busbars remains connected to the plastics material of the web during the extraction of the silicon. By contrast, the busbars leading from the top side of the wafer to the opposite web still adhere to the plastics film.

In some cases in which the absorbing material layer is embedded between two plastics films and the exposure of the absorbing material layer takes place with a minimum light dose through a transparent material layer, it may be advantageous to perform the separating method with two exposure steps. In the first exposure step, the pockets described above are produced by means of a first exposure with a light dose smaller than the minimum light dose, and they are filled with gas and opened at the predetermined breaking locations.

The pockets are created in this configuration at that plastics film which faces away from the incidence of light with reference to the absorbing material layer, said plastics film also being referred to here as lower plastics film. The evolution of gas and separation associated therewith likewise take place, however, albeit to a smaller extent, at the upper plastics film facing the incidence of light. In this case, the absorbing material layer may not be detached or may be only incompletely detached from the upper plastics film. By means of a second, temporally succeeding exposure, it is possible to completely open the pockets of the lower plastics film and to detach the at least still sectionally adhering absorbing material layer from the upper plastics film.

During said first exposure, a longer exposure duration than that of the succeeding exposure is preferably used since, in order to open the pockets, the silicon surface adjoining the lower plastics film is intended to be heated, but the light absorption takes place at the opposite silicon surface adjoining the upper plastics film. A certain material-dependent time is thus required for heat transfer from the front side to the back side of the absorbing material layer. During the second exposure, by contrast, a significantly shorter exposure duration is sufficient, for example shorter than the first exposure duration by a factor of ten to a hundred, since here the heating of the upper surface of the absorbing material layer is desired for complete detachment of the absorbing material layer from the upper plastics film and thus from the transparent material layer.

Ideally, in this method variant, the maximum pressure generated by the pyrolysis gases, by means of two successive exposures, is reduced in comparison with a single exposure. Disadvantageous effects such as pressure waves on the transparent material layer, often consisting of glass, or on the light source or instances of blackening as a result of the pyrolysis gases can be minimized by the double exposure.

Moreover, it is possible to reduce the maximum temperature of the transparent material layer as a result of a double exposure and the consequences associated therewith. By way of example, during a single exposure, greatly heated fragments of the absorbing material layer may impinge on the underside of the lower plastics film and be fused therein. If this or other negative effects on account of a high energy density of a single-stage exposure may also occur for other embodiments of composite components, a two-stage exposure may be applied in these cases as well.

For both exposure times, the variants described above are applicable depending on the parameters of the relevant composite components. If the temporal interval between the exposures is chosen to be sufficiently short so that the absorbing material layer is at a higher temperature at the start of the second exposure than at the start of the first exposure, the dose of the second exposure can be reduced in order to save energy. In a further variant of this embodiment of the method, the first exposure step can also be implemented with a plurality of stages.

The method described above is applicable to such composite components whose absorbing material layer is formed by a plurality of wafers, in which case multiple wafers, alternatively all wafers, are arranged and exposed in the exposure field. If these are separated from one another by webs, then the pockets that form are delimited by the webs and an effective and reproducible implementation of the method with a high throughput is possible.

The invention will be explained in greater detail below on the basis of an exemplary embodiment by way of example and in a nonlimiting manner.

### BRIEF DESCRIPTION OF THE DRAWINGS

FIG. 1 shows the schematic construction of a photovoltaic module as a composite component in accordance with the prior art, and

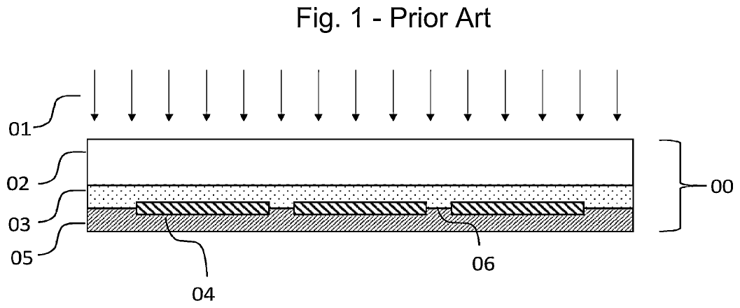

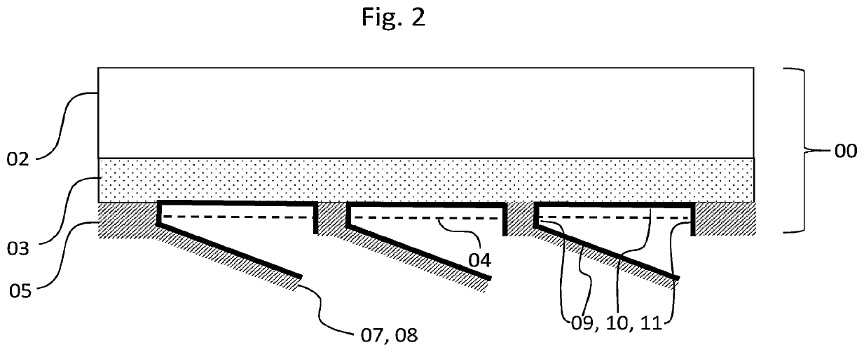

FIG. shows a schematic illustration of a composite component in accordance with FIG. 1 after the method for separating reusable materials has been carried out.

### DETAILED DESCRIPTION

The figures show the subject matter of the invention merely schematically and to an extent such as is required for understanding the invention. They do not claim to be complete or to scale.

With regard to FIG. 1, reference is made to the above explanations with regard to the prior art about the construction of a photovoltaic module 00 as an example of a composite component that can be treated by the method. The currently preferred composite component is a photovoltaic module comprising front-side glass and back-side film. However, the method is also applicable to other composite components having in principle a comparable layer construction.

FIG. 2 shows the composite component after the method for separating reusable materials of a composite component has been carried out, wherein the lower plastics film 05 was cut open in sections in the edge region 07 of the wafers 04 (illustrated in a dashed manner) and the wafers 04 were removed.

In order to separate the wafers 04 from the upper plastics film 03 and the lower plastics film 05, firstly predetermined breaking locations 08 are introduced into the lower plastics film 05 by means of lasers (not illustrated), alternatively by a mechanical knife. The predetermined breaking locations 08 extend around the wafer 04 in the edge region 07 thereof, but not fully circumferentially.

Subsequently, the photovoltaic module 00 is exposed for 10 milliseconds by means of cylindrical flash lamps (not illustrated), which are arranged parallel in one plane, within an exposure field which is parallel to the lamp plane and which includes all the illustrated wafers (the exposure being represented by a multiplicity of arrows extending parallel in FIG. 1). The light from the flash lamps leads to a high level of heating of the wafers 04, which function as a light-absorbing material layer here. In the boundary layers 09 of the upper plastics film 03 and the lower plastics film 05, thermal decomposition processes are initiated, thus resulting in the formation of pyrolysis gases in both boundary layers with respect to the wafer 04.

In the lower plastics film 05 and in the upper plastics film 03, said pyrolysis gases firstly lead to the inflation of film pockets 10, in each of which a wafer 04 is embedded, and to the breaking of the lower plastics film 05 along the predetermined breaking locations 08.

The pyrolysis gases of the upper plastics film 03 accumulate as gas layer 11 (illustrated as a thick black line) in the boundary layer 09 and here, too, cause separation of the wafers 04 from the upper plastics film 03. A gas layer 11 such as is illustrated at the top side of the wafer 04 also forms at the underside thereof. The gas of the lower gas layer escapes after the breaking of the predetermined breaking locations 08.

On account of the lower plastics film 05 undergoing instances of breaking at each wafer 04, the pockets 10 open and the wafers 04 which have been separated from both plastics films 03, 05 under the action of the pressure of the pyrolysis gases can now drop out of the open pockets 10. On account of the pressure, the wafer 04 breaks apart usually into pieces up to several square centimeters in size, which are hurled out of the pocket 10 when the flap opens. The silicon can now easily be separated from the further materials.

If the edge regions 07 of the wafers 04 have been cut fully circumferentially, the regions of the lower plastics film 05 which cover the wafer 04 can completely separate from the rest of the module and uncover the wafer 04 for extraction.

In summary, the method affords the following advantages, inter alia:
The method is suitable for extracting reusable materials from various composite components. The gases created during a thermal decomposition of plastics materials support the separation process, such that, owing to the predetermined breaking locations, the reusable material can emerge from the composite component in a targeted manner.
The preferred radiation source is one or more gas discharge lamps, for example flash lamps on account of the steep heating ramps that are generable therewith, and also the possibility of processing areas several square meters in size in less than a second.
The predetermined breaking locations are able to be chosen such that after the separation of the material composite, individual material layers are not mixed as a fraction with the extracted reusable material.
The method is implementable in a single stage and in a plurality of stages and is thus adaptable to different composite components.
The extraction of reusable materials takes place more effectively with regard to energy expenditure and yield of reusable materials and, in principle, is also usable for continuous methods.
By means of the method, the created pyrolysis gases are guided away in a targeted manner from the side of the composite material facing away from the exposure source, and this prevents the light source from being adversely affected or damaged. This makes it possible, for example, to process photovoltaic modules with a broken front glass sheet in accordance with the method in the patent application WO 2018/137735 A1.

### LIST OF REFERENCE SIGNS

00 composite component
01 exposure
02 transparent material layer
03 upper plastics film
04 absorbing material layer, wafer
05 lower plastics film
06 web
07 edge region
08 predetermined breaking location
09 boundary layer
10 film pocket
11 gas layer

1.-12. (canceled)

13. A method, comprising:
providing a radiation source having an exposure field;
providing a composite component (00) having multiple material layers, including an energy-absorbing material layer (04), and
a film (05) made of a plastic material, the film (05) having a boundary layer (09) that faces the energy-absorbing material layer (04);
introducing a predetermined breaking location (08) into the film (05);
arranging the composite component (00) such that the exposure field covers at least a portion of a surface of the composite component (00);
heating the energy-absorbing material layer (04) with the radiation source for less than one second and thereby
cleaving chemical compounds of the plastic material and creating a gas in the exposure field, and
breaking the film (05) under pressure of the created gas at the predetermined breaking location (08).

14. The method as in claim 13,
wherein the film (05) adjoins the energy-absorbing material layer (04) directly.

15. The method as in claim 13,
wherein the film (05) adjoins the energy-absorbing material layer (04) indirectly, and
wherein a thermally conductive layer is interposed between the energy-absorbing material layer (04) and the film (05).

16. The method as claimed in claim 13,
wherein arranging the composite component (00) is performed such that the surface of the composite component (00) covered at least partially by the exposure field faces away from the predetermined breaking location (08).

17. The method as claimed in claim 13,
wherein the multiple material layers of the composite component (00) further include a transparent material layer (02) which is transparent to visible light, having a transparency of more than 40%, and
wherein heating the energy-absorbing material layer (04) takes place through the transparent material layer (02).

18. The method as claimed in claim 13,
wherein introducing the predetermined breaking location (08) into the film (05) is part of introducing a plurality of predetermined breaking locations (08) into the film (05),
wherein a geometric configuration of the plurality of predetermined breaking locations (08) and a distribution thereof on the film (05) are selected such that the film (05) remains as a continuous layer having openings within the exposure field after causing the film (05) to break under the pressure of the created gas at the plurality of predetermined breaking locations (08).

19. The method as claimed in claim 13,
wherein the composite component (00) is a photovoltaic module,
wherein the energy-absorbing material layer (04) includes busbars, and
wherein regions over the busbars of the photovoltaic module remain as continuous regions after heating and breaking.

20. The method as claimed in claim 13,
wherein the multiple material layers include a second film (03), the energy-absorbing material layer (04) being arranged between the film (05) and the second film (03),
wherein heating the energy-absorbing material layer (04) includes irradiating the energy-absorbing material layer (04) with a minimum light dose from the radiation source that causes the energy-absorbing material layer (04) to detach from the second film (03) at least in sections.

21. The method as claimed in claim 20,
wherein heating the energy-absorbing material layer (04) is performed in two steps,
wherein in a first heating step the energy-absorbing material layer (04) is irradiated and heated in less than a second with a light dose which is less than the minimum light dose but sufficient to cause breaking the film (05) at the predetermined breaking location (08), and
wherein irradiating the energy-absorbing material layer (04) with the minimum light dose is performed in a second heating step.

22. The method as claimed in claim 21,
wherein the second heating step is separated from the first heating step by a temporal interval which results in a temperature of the energy-absorbing material layer (04) at a beginning of the second heating step to be higher than at a beginning of the first heating step.

23. The method as claimed in claim 21,
wherein the first heating step lasts longer than the second heating step.

24. The method as claimed in claim 21,
wherein the first heating step is implemented in one or more parts.

25. The method as claimed in claim 13,
wherein introducing the predetermined breaking location (08) into the film (05) is performed mechanically.

26. The method as claimed in claim 13,
wherein introducing the predetermined breaking location (08) into the film (05) is performed by a laser.

27. The method as claimed in claim 13,
wherein the energy-absorbing material layer (04) comprises a plurality of wafers and
wherein the exposure field cover n wafers, n being a natural number greater or equal to one.

28. The method as claimed in claim 13,
wherein the radiation source is a gas discharge lamp.

29. The method as claimed in claim 13,
wherein the radiation source is a laser.
